(19) United States
(12) Patent Application Publication
(10) Pub. No.: US 2003/0110427 A1
(43) Pub. Date: Jun. 12, 2003

(54) Semiconductor test system storing pin calibration data in non-volatile memory

(75) Inventors: Rochit Rajsuman, Santa Clara, CA (US); Robert Sauer, Santa Clara, CA (US); James Alan Turnquist, Santa Clara, CA (US); Hiroki Yamoto, Santa Clara, CA (US); Shigeru Sugamori, Ora-gun (JP)

Correspondence Address: Glenn M. Kubota, Morrison & Foerster LLP, 35th Floor, 555 W. 5th Street, Los Angeles, CA, 90013, US

(73) Assignee: ADVANTEST CORPORATION, Ora-gun (JP)

(21) Appl. No.: 10/340,349

(22) Filed: Jan. 10, 2003

Related U.S. Application Data
(63) Continuation-in-part of application No. 09/547,752, filed on Apr. 12, 2000.

(51) Int. Cl. G01R 31/28

(52) U.S. Cl. 714/724

(57) ABSTRACT

A semiconductor test system is disclosed which accepts pincards from multiple vendors, each pincard including a local non-volatile memory in which specific calibration data can be stored. Each pincard in the test system may be capable of performing different types of tests on the DUT. Non-volatile memory on the pincard is used to store pincard calibration data, and loadboard and socket related calibration data may also be stored locally in the non-volatile memory of each pincard for use in compensating for signal degradation. Calibration data related to pincard slots (i.e. slot-to-slot skew) may be stored in nonvolatile memory on a test system backplane and used to calibrate slot-to-slot skew of the pincard.

### CROSS-REFERENCE TO RELATED APPLICATIONS

This application is a Continuation-in-Part (CIP) of U.S. utility application Ser. No. 09/547,752 entitled “Event Based Test System Storing Pin Calibration Data in Non-Volatile Memory,” filed Apr. 12, 2000, the contents of which are incorporated herein by reference for all purposes.

### FIELD OF THE INVENTION

This invention relates to a semiconductor test system for testing semiconductor devices such as ICs, and more particularly, to a semiconductor test system in which calibration data concerning various parameters affecting test accuracy with respect to each pin unit is stored in a non-volatile memory within a pin card and calibration data concerning pincard slots is stored in a non-volatile memory within the backplane through which the pincards are connected.

### BACKGROUND OF THE INVENTION

In testing semiconductor devices such as ICs and LSIs by a semiconductor test system, such as an IC tester, a semiconductor IC device to be tested is provided with test signals or test patterns produced by an IC tester at its appropriate tester pins at predetermined test timings. The IC tester receives output signals from the IC device under test in response to the test signals. The output signals are strobed or sampled by strobe signals at predetermined timings to be compared with expected output data to determine whether the IC device functions correctly.

The test signals are transmitted to the device under test through drivers which establish intended amplitude, impedance and slew rate of the test signals. The output response signals from the device under test are sampled by analog comparators by the timings of the strobe signals to be compared with predetermined threshold voltages. Both the drivers and analog comparators are typically assembled in a block called a pin electronics. Since the pin electronics involves analog values of the test signals and response signals as well as DC voltages and currents for DC parametric measurement, parameters in the pin electronics need to be calibrated to insure accurate measurement. This invention is directed to storage of such calibration data in the semiconductor test system.

Traditionally, timings of the test signals and strobe signals are defined relative to a tester rate or a tester cycle of the semiconductor test system. Such a test system is sometimes called a cycle based test system. Another type of test system is called an event based test system wherein the desired test signals and strobe signals are produced by event data from an event memory directly on a per pin basis. The present invention is better suited to such an event based semiconductor test system, although the present invention is also applicable to the traditional cycle based semiconductor test system.

In an event based test system, notion of events are employed, which are any changes of the logic state in signals to be used for testing a semiconductor device under test. For example, such changes are rising and falling edges of test signals or timing edges of strobe signals. The timings of the events are defined with respect to a time length from a reference time point. Typically, such a reference time point is a timing of the previous event. Alternatively, such a reference time point is a fixed start time common to all of the events.

In an event based test system, since the timing data in a timing memory (event memory) does not need to include complicated information regarding waveform, vector, delay and etc. at each and every test cycle, the description of the timing data can be dramatically simplified. In the event based test system, as noted above, typically, the timing (event) data for each event stored in an event memory is expressed by a time difference between the current event and the last event. Typically, such a time difference between the adjacent events (delta time) is small, unlike a time difference from a fixed start point (absolute time), a size of the data in the memory can also be small, resulting in the reduction of the memory capacity.

As noted above, the pin electronics circuits in the semiconductor test system need the calibration for achieving accurate measurement of the device parameters. An example of types of calibration data that may be needed in a semiconductor test system includes (1) compensation of reference driving voltage, (2) compensation of reference comparison (threshold) voltage, (3) compensation of driving current load, (4) compensation of parametric (DC voltage and current) measurement circuits connected to the test pin, (5) compensation of timing strobes used to trigger comparisons, and (6) compensation of timing triggers used to drive test pin stimulus (test signals). There are other error factors which also affect accuracy and resolution of the test result. Such other error factors include signal propagation delay times in a performance board and a pin fixture (HiFix and fixture) provided between the pin cards and the device under test.

Both the drivers and analog comparators are typically assembled in blocks known as pin units or pin electronics. The test signals sent to the DUT and the output signals received from the DUT must pass through signal paths that can create considerable signal degradation due to the hardware and physical dimensions of modern test systems. Referring to the example test system 80 of FIG. 9, test vectors from pin unit 82 on pincard 98 may need to pass through a driver/comparator circuit 84, cabling 86, “pogo pins” 88, traces 90 on loadboard 92, socket 94, and finally into DUT 96. Output signals must return to the pin unit 82 through a similar path.

These paths are generally long, and contain parasitic resistances and capacitances (RCs) which can slow down the signals, slow down rise and fall times, reduce voltage swings, and the like. Because testing of the DUT can require precise control of the AC and DC characteristics of input test signals and precise measurement of output signal timing and parametrics, test signals and output signals in the pin units 82 need to be calibrated to account for signal degradation and ensure accurate measurements.

An exemplary general structure of an open architecture test system is illustrated in FIG. 10. This open architecture test system uses pincards 100 from multiple vendors (vendor A to vendor F in the example of FIG. 10). The design of each pincard 100 is vendor-specific and DUT-specific and will therefore be different from other pincards. Due to the use of pincards from different vendors, such test systems present a major calibration challenge.

In existing test systems, factory and field calibration data for each pincard is saved on an external storage device such as a floppy disk or compact disk. This stored data is given to the user as a physically separate entity from the associated pincard. Because of this separation of the calibration data and the pincards, these items must be tracked closely for inventory purposes, during pincard installation into a test system, and during pincard or ATE maintenance. This lack of co-location is compounded in an open architecture test system due to the existence of multiple vendor pincards and their associated separate calibration data.

Besides the difficulties in tracking the vendor pincards and their associated separate calibration data, having calibration data separate from the pincard creates additional functional burdens. For example, the existence of separate calibration data requires that the test system locate and read correct calibration data (correct vendor and pincard type) from an external storage device and configure the card. Furthermore, if the external storage device is corrupted (such as a corrupted floppy disk), all card calibration data may be lost. In an open architecture test system with pincards from multiple vendors, the malfunction of a few pins may occur from time to time. However, identification and correction of those pins may require a complete factory calibration of all pins in the system. This can be a lengthy process requiring the transport and connection of special calibration equipment. In addition, when a pincard is moved to a different slot within a system or to a new system, calibration data must be copied and mapped to the new slot. Installing a new pincard requires that the calibration files accompany the pincard, and also requires updating and mapping of calibration and associated data files. When several pincards are removed from the system for maintenance, special care must be taken to ensure that they are placed back in the same slots from which they were removed.

Therefore, there is a need to establish an effective way to maintain calibration data in the test system so that the compensation of various parameters can be conducted at a certain time interval or at each power up, and to eliminate the inventory, configuration, and calibration difficulties that occur when the calibration data is separate from the pincard.

### SUMMARY OF THE INVENTION

Therefore, it is an object of the present invention to provide a semiconductor test system having a plurality of pin cards in which calibration data is stored locally on the pin card where each pin card includes a plurality of pin units where each pin unit is configured as an event based tester, a cycle based tester, an analog tester, a parametric tester, a functional tester, a mixed signal tester, a memory tester, or any combination thereof.

It is another object of the present invention to provide a semiconductor test system wherein each pin card having a plurality of pin units therein includes a non-volatile memory to store the calibration data of various parameters involved in the pin units in the pin card.

It is a further object of the present invention to provide a semiconductor test system wherein each pin card includes a plurality of pin units configured as an event based tester, a cycle based tester, an analog tester, a parametric tester, a functional tester, a mixed signal tester, a memory tester, or any combination thereof, the plurality of pin units therein further including a non-volatile memory for storing the calibration data of various parameters involved in the pin units.

It is a further object of the present invention to provide a semiconductor test system having a plurality of pin cards, each pin card including a plurality of pin units configured as an event based tester, a cycle based tester, an analog tester, a parametric tester, an at-speed functional tester, a mixed signal tester, a memory tester, or any combination thereof, the semiconductor test system having a cost effective, error free, secure and simple way of managing the calibration data for all of the pin cards used therein.

In the present invention, the semiconductor test system is comprised of a large number of test channels for testing a semiconductor device under test (DUT). The test system is comprised of a plurality of pin cards each having a plurality of pin units therein to establish a part of the test channels, a non-volatile memory provided within each pin card for storing calibration data for compensating error factors involved in the pin units mounted in the corresponding pin card. A microprocessor may also be provided within each pin card for managing the calibration data and executing the calibration procedure for all of the pin units in the corresponding pin card, where each pin unit is configured as an event based tester, a cycle based tester, an analog tester, a parametric tester, a functional tester, a mixed signal tester, a memory tester, or any combination thereof.

The calibration data includes data for compensating error factors regarding parameters used in the corresponding pin card in testing the DUT. For example, the calibration data includes data for compensating error factors including timings and reference voltages of the test patterns, timings of strobe signals and reference comparison voltages.

In a further aspect, the test system of the present invention further includes a performance board unique to the DUT for mounting the DUT thereon and having signal paths for transmitting signals to and from the DUT, and a pin fixture for interconnecting the plurality of pin cards in the test system with the performance board. In such a configuration, it is preferable that the calibration data includes data for compensating error factors including timings and reference voltages of test patterns, timings of strobe signals, reference comparison voltages, and signal propagation delays in the performance board and pin fixture.

According to the present invention, the semiconductor test system is configured to include a non-volatile memory storing calibration data in each pin card to compensate the error factors in all pin units in the pin card. Because the memory storing the calibration data is fixedly provided to the pin card, management of the calibration data by a manufacturer or a user of the test system is simplified such as in processes of inventory, pin card replacement, updating the calibration data, and etc. Since pin card includes a local microprocessor, a calibration process including data mapping for the pin units in the pin card is also simplified. According to the present invention, the event based test system is able to achieve a cost effective, error free, secure and simple way of managing the calibration data for all of the pin cards.

The non-volatile memory on the pincard is used to store calibration data to compensate for degradations due to the pincard, loadboard or socket. Calibration data related to pincard slots may be stored in nonvolatile memory on a test system backplane and used to calibrate the pincard slot-to-slot skew.

Examples of calibration data that may be stored in the non-volatile memory of the pincard or the test system backplane include, but are not limited to: (i) compensation of reference driving voltages; (ii) compensation of reference comparison voltages; (iii) compensation of driving current loads; (iv) compensation of parametric measurement circuits connected to the test pins; (v) compensation of timing strobes used to trigger comparisons; and (vi) compensation of timing triggers used to drive test pin stimuli.

An open architecture test system that accepts pincards from multiple vendors, wherein each pincard includes a local non-volatile memory in which specific calibration data can be stored, can provide specific benefits. For example, having calibration information locally available on the pincard allows for easy configuration of the hardware and permits the use of different pincards from multiple vendors. Because each pincard can carry calibration data, no extra associated data files are needed to read the calibration data from an external compact disk (CD). In addition, a user does not need to maintain any specific pincard slot mapping file information or any specific pincard calibration file information in the test system or associated host computer. Having calibration information locally available on the pincard also improves system reliability because less information needs to be maintained external to the system, resulting in calibration data becoming tightly coupled to its associated pincard. The test system can also be easily updated by updating calibration data in the nonvolatile memory with new calibration data to compensate for component value changes over time.

### BRIEF DESCRIPTION OF THE DRAWINGS

FIG. 1 is a schematic block diagram showing a basic structure of an event based test system of the present invention.

FIG. 2 is a block diagram showing a more detailed structure concerning the pin electronics of FIG. 1 and associated drive events (test signal) and sampling event (strobe signal) from the event generator.

FIG. 3 is a schematic diagram showing an example of external appearance of an event based test system including a performance board and a pin fixture between the device under test and the pin cards.

FIG. 4 is a schematic block diagram showing a basic concept of the present invention where the calibration data is stored in a non-volatile memory provided in each pin card in the test system.

FIG. 5 is a schematic block diagram showing another approach for storing the calibration data in the test system where an external storage device provided separately from the pin cards stores the calibration data.

FIG. 6 is a block diagram showing an example of structure in the event based test system having a plurality of pin cards where each pin card includes a plurality of pin units or event testers.

FIG. 7 is a schematic block diagram showing an example of concept in another embodiment of the present invention where the calibration data includes data for compensating propagation delay times involved in a performance board and a pin fixture.

FIG. 8 shows an example of program written in “C” programming language for initiating a calibration process at the time of power up in the test system.

FIG. 9 illustrates an example path for a test pattern in conventional Automatic Test Equipment systems.

FIG. 10 is an exemplary illustration of an open architecture test system.

FIG. 11 is a more detailed exemplary block diagram of an open architecture test system with calibration data stored in nonvolatile memory on the pincard according to an embodiment of the present invention.

FIG. 12 is an exemplary block diagram of an open architecture test system with pincard slot calibration data stored in nonvolatile memory on the backplane according to an embodiment of the present invention.

### DETAILED DESCRIPTION OF THE PREFERRED EMBODIMENT

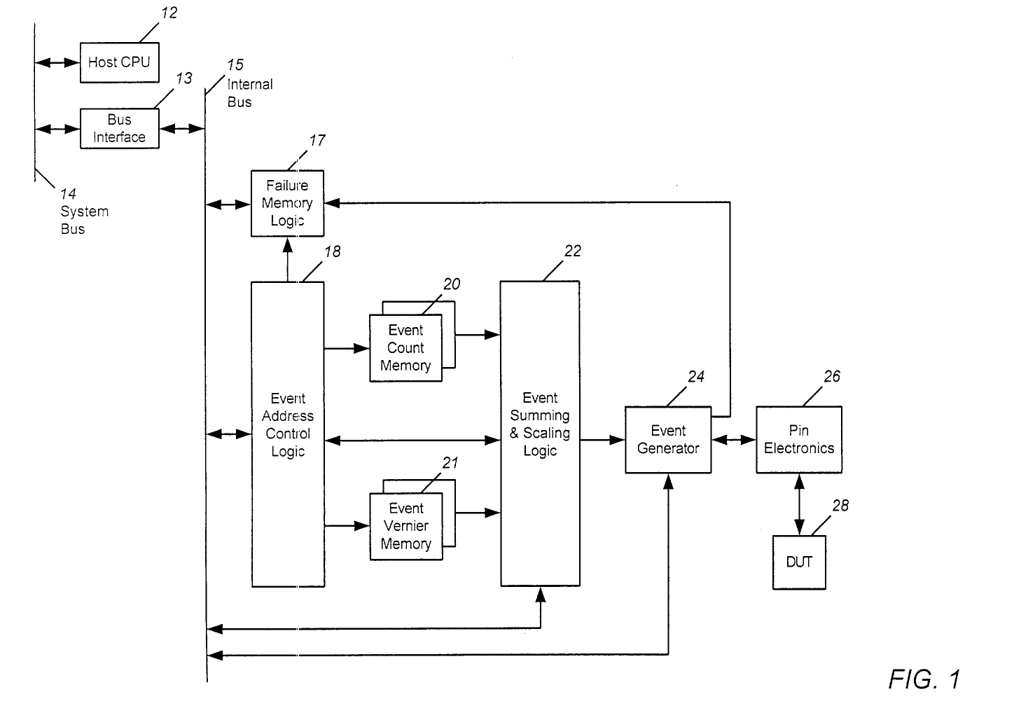

FIG. 1 is a schematic block diagram showing an example of basic structure in a semiconductor test system of the test system which is preferably an event based test system. The event based test system includes a host computer 12 and a bus interface 13 both are connected to a system bus (pin bus) 14, an internal bus 15, an address control logic 18, a failure memory 17, an event memory consists of an event count memory 20 and an event vernier memory 21, an event summing and scaling logic 22, an event generator 24, and a pin electronics (driver and comparator) 26. The event based test system is to evaluate a semiconductor device under test (DUT) 28, which is typically a memory IC such as a random access memory (RAM) and a flash memory or a logic IC such as a microprocessor and a digital signal processor, connected to the pin electronics 26.

An example of host computer 12 is a work station having a UNIX, Window NT, or Linux operating system therein. The host computer 12 functions as a user interface to enable a user to instruct the start and stop operation of the test, to load a test program and other test conditions, or to perform test result analysis in the host computer. The host computer 12 interfaces with a hardware test system through the system bus 14 and the bus interface 13. Although not shown, the host computer 12 is preferably connected to a communication network to send or receive test information from other test systems or computer networks.

The internal bus 15 is a bus in the hardware test system and is commonly connected to most of the functional blocks such as the address control logic 18, failure memory 17, event summing and scaling logic 22, and event generator 24. An example of address control logic 18 is a tester processor which is exclusive to the hardware test system and is not accessible by a user. The tester processor 18 provides instructions to other functional blocks in the test system based on the test program and conditions from the host computer 12. The failure memory 17 stores test results, such as failure information of the DUT 28, in the addresses defined by the address control logic 18. The information stored in the failure memory 17 is used in the failure analysis stage of the device under test.

The address control logic (address sequencer) 18 provides address data to the event count memory 20 and the event vernier memory 21. In an actual test system, plural sets of event count memory and event vernier memory will be provided, each set of which may correspond to a test pin of the test system. The event count and vernier memories store the timing data for each event of the test signals and strobe signals. The event count memory 20 stores the timing data which is an integer multiple of the reference clock (integral part), and the event vernier memory 21 stores timing data which is a fraction of the reference clock (fractional part). Within the context of the present invention, the timing data for each event is expressed by a time difference (delay time or delta time) from the previous event.

The event summing and scaling logic 22 is to produce data showing overall timing of each event based on the delta timing data from the event count memory 20 and event vernier memory 21. Basically, such overall timing data is produced by summing the integer multiple data and the fractional data. During the process of summing the timing data, a carry over operation of the fractional data (offset to the integer data) is also conducted in the timing count and offset logic 22. Further during the process of producing the overall timing, timing data may be modified by a scaling factor so that the overall timing be modified accordingly.

The event generator 24 is to actually generate the events based on the overall timing data from the event summing and scaling logic 22. The events (test signals and strobe signals) thus generated are provided to the DUT 28 through the pin electronics 26. Basically, the pin electronics 26 is formed of a large number of components, each of which includes a driver and a comparator as well as switches to establish input and output relationships with respect to the DUT 28.

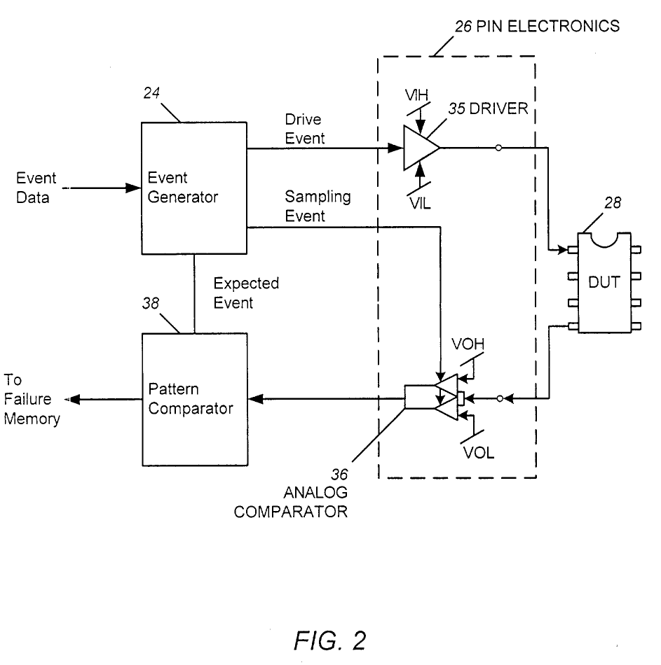

FIG. 2 is a block diagram showing a more detailed structure in the pin electronics 26 having a driver 35 and an analog comparator 36. The event generator 24 produces drive events which are provided to an input pin of the DUT 28 as a test signal (test pattern) through the driver 35. The event generator 24 further produces a sampling event which is provided to the analog comparator 36 as a strobe signal for sampling an output signal of the DUT 28. The output signal of the analog comparator 36 is compared with the expected data from the event generator 24 by a pattern comparator 38. If there is a mismatch between the two, a failure signal is sent to the failure memory 17 in FIG. 1.

Although not shown, the pin electronics 26 also includes a circuitry for performing DC parametric test. The DC parametric test includes measurement of DC current flowing in a particular device pin while providing a reference DC voltage to the pin, or measurement of DC voltage at a particular device pin while supplying a reference DC current thereto. The pin electronics 26 may also include a circuit arrangement for changing source voltages to the device under test terminal resistors for device pins.

Because the pin electronics 26 involves various analog parameters noted above, and such parameters vary depending on the components used in the test system, physical positions and layouts in the test system, as well as time and environmental changes. Therefore, it is necessary to calibrate these parameters to ensure accurate test results on the semiconductor device under test.

An example of types of calibration data that may be needed in a semiconductor test system is reiterated here, i.e., (1) compensation of reference driving voltage, (2) compensation of reference comparison (threshold) voltage, (3) compensation of driving current load, (4) compensation of parametric (DC voltage and current) measurement circuits connected to the test pin, (5) compensation of timing strobes used to trigger comparisons, and (6) compensation of timing triggers used to drive test pin stimulus (test signals).

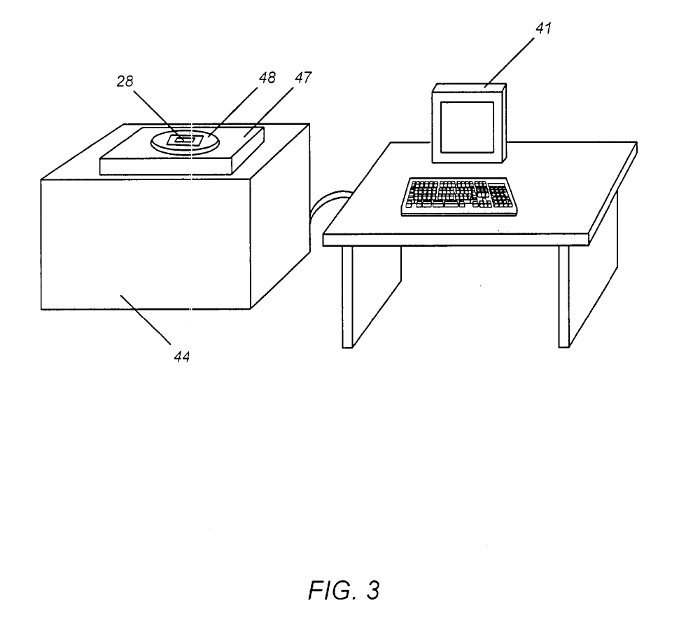

It should also be noted that in the actual test system, the test signal is supplied to the device under test through a performance board and a pin fixture (performance board adapter). FIG. 3 is a schematic diagram showing an example of external appearance of an event based test system including a performance board and a pin fixture between the device under test and the pin electronics (mounted on a pin card). Signal propagation delays involved in the performance board and pin fixture also affect the test accuracy and resolution in the semiconductor device test.

In the example of FIG. 3, semiconductor device under test (DUT) 28 is placed on a performance board 48 which is unique to a type of device to be tested. A plurality of pin cards are installed in a main frame 44. The performance board and the pin cards (not shown) are interfaced by a pin fixture (performance board adapter) 47. Typically, the pin fixture is a mechanical block having a large number of flexible contact pins such as pogo-pins to electrically connect the pin cards to the performance board 48.

As noted in the foregoing, the semiconductor test system must be calibrated as to various parameters for accurate measurement of the semiconductor device parameters. Calibration data is obtained by a manufacturer and stored in a storage device as factory calibration data. The calibration data may be modified or added by a user in the storage device as field calibration data. Based on the calibration data, errors involved in various parameters are compensated in a fixed time interval or at each power up.

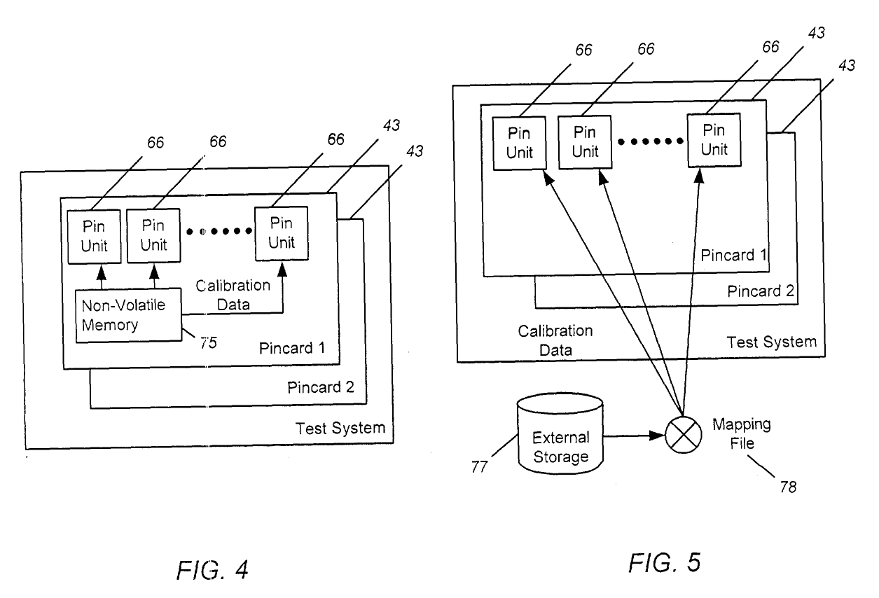

FIG. 4 is a schematic diagram showing the basic concept of the present invention for storing the calibration data in the test system. In the present invention, each pin card 43 includes a memory 75 to store the calibration data therein. The memory 75 is a non-volatile memory, such as a flash memory, so as to maintain the data when the source power is off. The non-volatile memory 75 stores all of the calibration data for the pin units 66 in the same pin card 43. Such a non-volatile memory can be in a various forms such as a stand alone memory or a part of other storage device.

Additionally, in open architecture embodiments of the present invention, the pincards 43 may be supplied from one or more vendors. In open architecture embodiments of the present invention, an open architecture test system accepts pincards 43 from multiple vendors, each pincard including a local non-volatile memory 75, such as an EEPROM or flash memory, in which specific calibration data can be stored. Each pincard in the test system may correspond to a different DUT, and may be capable of performing different types of tests on the DUT, including at-speed functional testing, parametric testing, analog testing, mixed signal testing, memory testing, and the like.

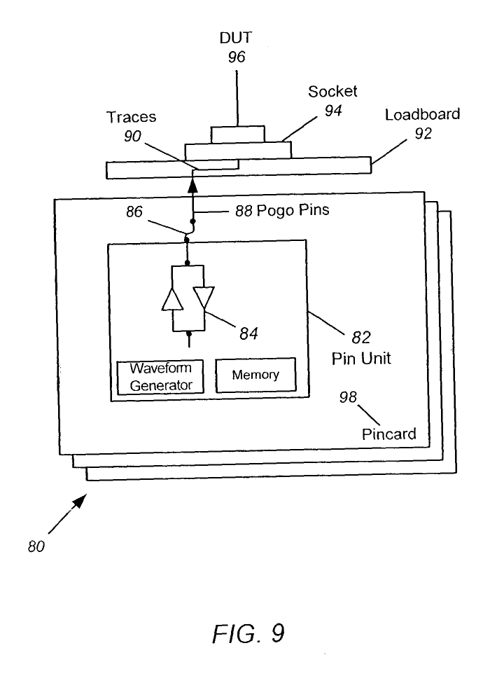

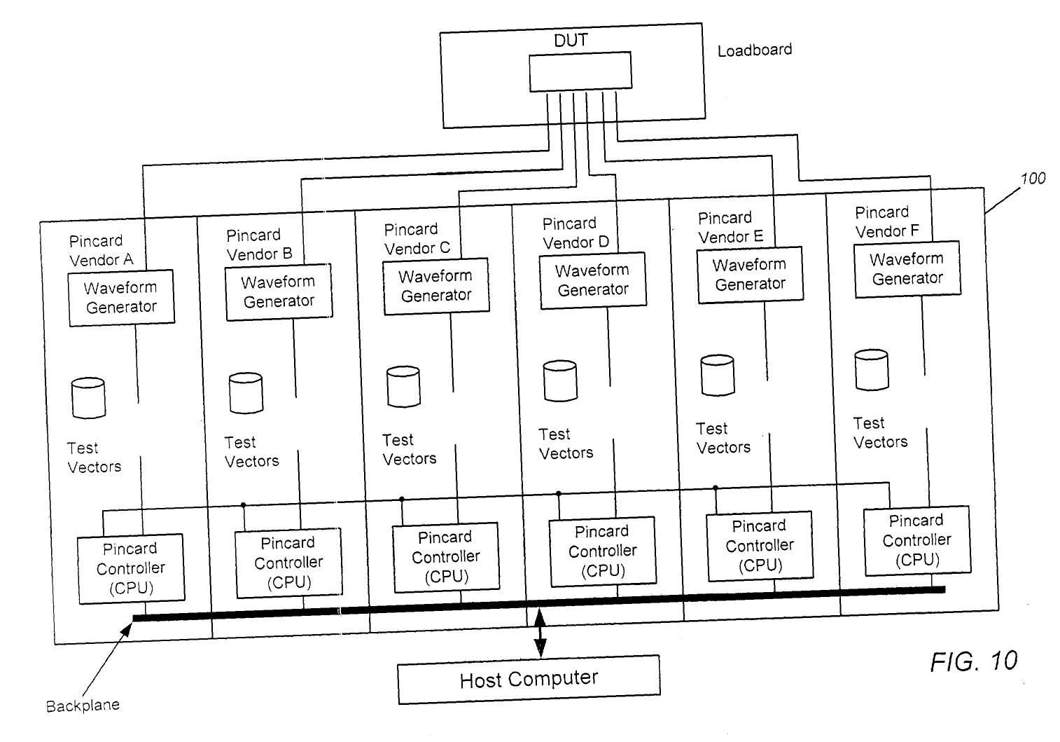

When a particular DUT is to be tested, a pincard specific to that DUT is installed into a particular slot in the test system, a loadboard and socket assembly specific to that DUT is mounted to the test system, and the test system must be configured to connect the DUT to the pincard specific to that DUT via the pogo pins for a particular slot (see FIG. 9). The pincard, slot hardware (pogo pins, cabling, and the like), loadboard and socket all contribute to signal degradation, and therefore calibration data for each of these items must be used when testing the DUT.

Pincard, loadboard and socket related calibration data will vary for each DUT type because the pincard, loadboard and socket will be different for each DUT. The use of non-volatile memory on the pincard therefore allows the test system to store this calibration data locally on each pincard and use it to compensate for these factors. In another embodiment, nonvolatile memory on the loadboard may be used to initially store loadboard and socket calibration data. The system processor may use the calibration data stored on the loadboard directly from the loadboard, or may transfer the calibration data to the nonvolatile memory on the pincard before use. This transfer may take place automatically, upon power up of the system, or it may occur at the direction of a user command.

Alternative embodiments may employ read only memory (ROM) on the pincard, but the use of ROM causes certain restrictions. When a ROM is used on the pincard to store slot-specific loadboard and socket calibration data, use of that pincard will be limited to a fixed slot. In other words, because ROM data cannot be changed, if the ROM stores loadboard and socket calibration data specific to slot A, for example, the pincard can only be used in slot A. If the pincard is plugged into slot B, the ROM calibration data becomes invalid.

Before further going into details of the present invention of FIG. 4, the description is made here regarding previous approaches. This example is shown in the block diagram of FIG. 5, wherein the calibration data for all of the pin cards, and thus all of the pin units of the test system, is stored in an external storage device 77.

The external storage device 77 saves factory and field calibration data regarding all of the pin units in the pin cards. The storage device 77 is, for example, a floppy disc or compact disc which is separated from the pin cards and is inserted in a host computer of a tester controller to read the calibration data therefrom. The calibration data for each pin unit is distributed by a mapping file 78 prepared in, for example, the host computer. It should be noted that although a dynamic random access memory (DRAM) or a static random access memory (SRAM) may be used on the pincards of conventional test systems to receive and store calibration data from the external storage device 77, the external storage device 77 cannot be eliminated because the contents of the DRAM/SRAM will be lost when a pincard is removed from the system and power is lost.

The inventors of this invention find that the structure of FIG. 5 having the external storage 77 separately from the pin cards in the test system is disadvantageous because of the following reasons:

The calibration items and calibration data must be tracked closely together in inventory of the pin cards, installation into a test system and system maintenance. The separation increases the overall manufacturing and maintenance cost. There is also an increase in the software because more complex system configuration software is needed to associate the external calibration data with its target pin cards. Moreover, having the calibration data external to the pin cards has the following deficiencies:

(1) It requires the test system to locate and read the calibration data from the external storage device and configure the pin card.

(2) If the external storage device is corrupted, calibration data for all pin cards may be lost, requiring an all new factory calibration of all pins in the test system, which can be a lengthy process requiring the transport and connection of special calibration equipment.

(3) When a pin card is moved to a new test system, the calibration data must be copied and mapped to the new system's card slot.

(4) Installing a new pin card on the test system requires the pin card calibration files accompanying the pin card and the updating of target test system's calibration mapping and data files.

(5) When several pin cards are removed from the test system for maintenance, care must be taken that they are placed exactly back in the same slots they originally came from.

Referring back to the present invention shown in FIG. 4, the calibration data is stored in the calibration memory 75 provided in each pin card 43. The calibration memory 75 is a non-volatile memory that can maintain the data when the power is turned off. Each pin card has a microprocessor that can read the calibration memory and write pin unit register (not shown). The advantages of present invention in storing the calibration data in a non-volatile memory in the target pin card are the following:

(1) With the card calibration information located on the pin board in a fixed location, it is easily configured into the hardware.

(2) Each board can carry with it their original factory calibration data with no extra associated data files to install.

(3) Users would not be required to maintain any specific pin card slot mapping file information. This would be done automatically from the data stored in the non-volatile memory found on each card.

(4) Users would not be required to maintain any specific pin card calibration file information. This would be done automatically from the data stored in the non-volatile memory found on each card.

(5) The test system reliability will be improved because less information needs to be maintained externally to the system and the calibration data is now tightly coupled directly to its associated pin card.

(6) The test system can easily update the non volatile memory with new calibration data to compensate for component value changes over time.

(7) A calibration storage system efficiently stores the calibration data locally on the test system pin card that is to be compensated.

(8) A non-volatile memory system stores the calibration data that is addressable by a processor to be used in the measurement and stimulus generation for device under test.

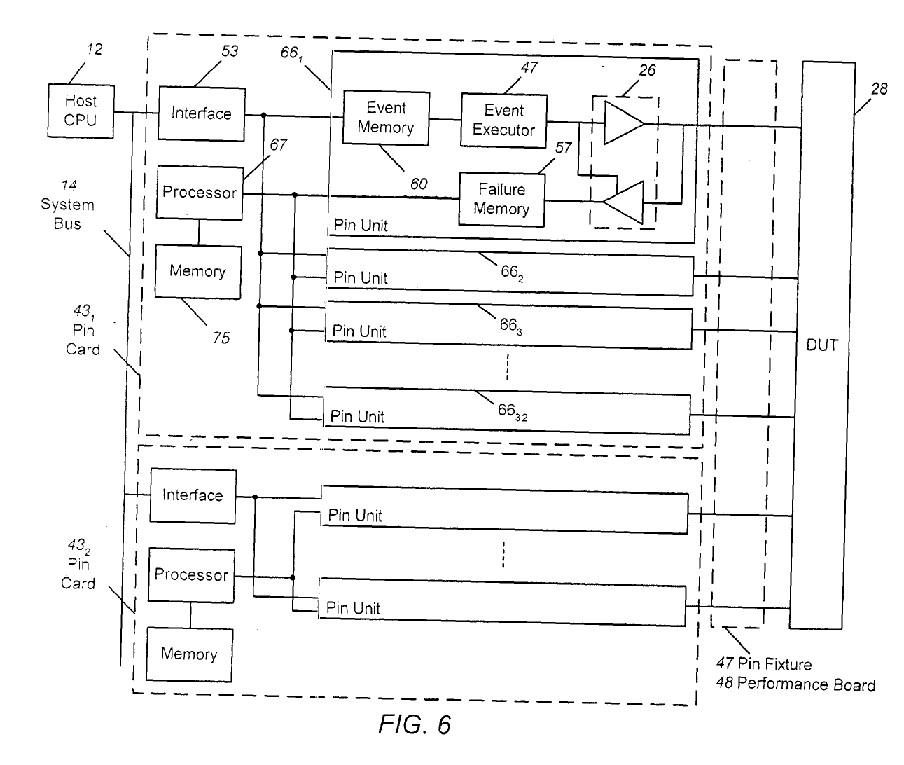

FIG. 6 is a block diagram showing a basic structure of the event based semiconductor test system of the present invention. The test system includes a plurality of pin cards 43. Further, each pin card includes a plurality of pin units (event testers) 66 corresponding to a plurality of tester pins, such as 32 pin units for 32 tester pins. In the test system of FIG. 6, the plurality of event pin cards 43 are controlled by a tester controller, which is a host computer of the test system, through a system bus (pin bus) 14.

In FIG. 6, the pin cards 43 apply test patterns (test signals) to the device under test 28, and examines response output signals from the device under test resultant from the test patterns. Between the pin cards 43 and the device under test 28, the test system includes the pin fixture 47 and the performance board 48 as shown in FIG. 3 as above.

Each pin card 43 includes pin units 66₁-66₃₂ for 32 tester pins, for example, an interface 53, a processor 67 and a memory 75. Each pin unit 66 corresponds to each tester pin in the event based test system, and has the same inner structure within the same tester board. In this example, the pin unit 66 includes an event memory 60, an event execution unit (event summing, scaling and event generation) 47, a pin electronics (driver and comparator) 26 and a test result (failure) memory 57. The memory 75 stores the calibration data as noted above as well as other data.

The event memory 60 stores event data for producing a test pattern. The event execution unit 47 produces the test pattern based on the event data from the event memory 60. The test pattern is supplied to the device under test through the pin electronics 26. An output signal of the device under test is compared with an expected signal by the comparator in the pin electronics 26, the result of which is stored in the test result memory 57.

As shown by the dotted line in FIG. 6, the device under test 28 and the pin electronics 26 are interfaced by the pin fixture 48 and the performance board 48. The test signals from the pin electronics (drivers) 26 to the device under test 28 may be affected by the signal propagation delay time in the pin fixture and the performance board. Similarly, the output signal from the device under test 28 to the pin electronics 26 (comparator) may be affected by the signal propagation delay time in the pin fixture and the performance board.

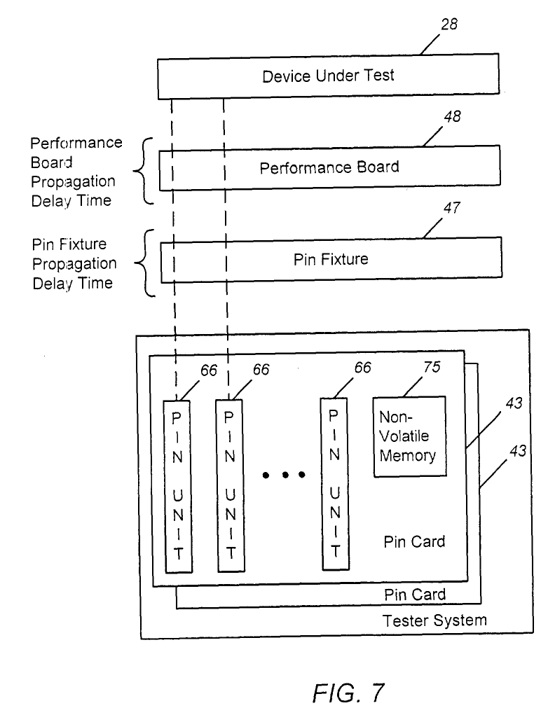

Therefore, FIG. 7 is a schematic block diagram showing another embodiment of the present invention where the calibration data includes data for compensating propagation delay times in the performance board and pin fixture. Although, the information concerning the propagation delay time in the pin fixture 47 and the performance board 48 is not directly related to the pin card 43 but is related to the pin unit total signal path length. Thus, it is useful to store calibration data concerning (1) specific performance board propagation delay time calibration data, and (2) pin card to pin fixture propagation delay time calibration data in the non-volatile memory 75 in the pin card 43.

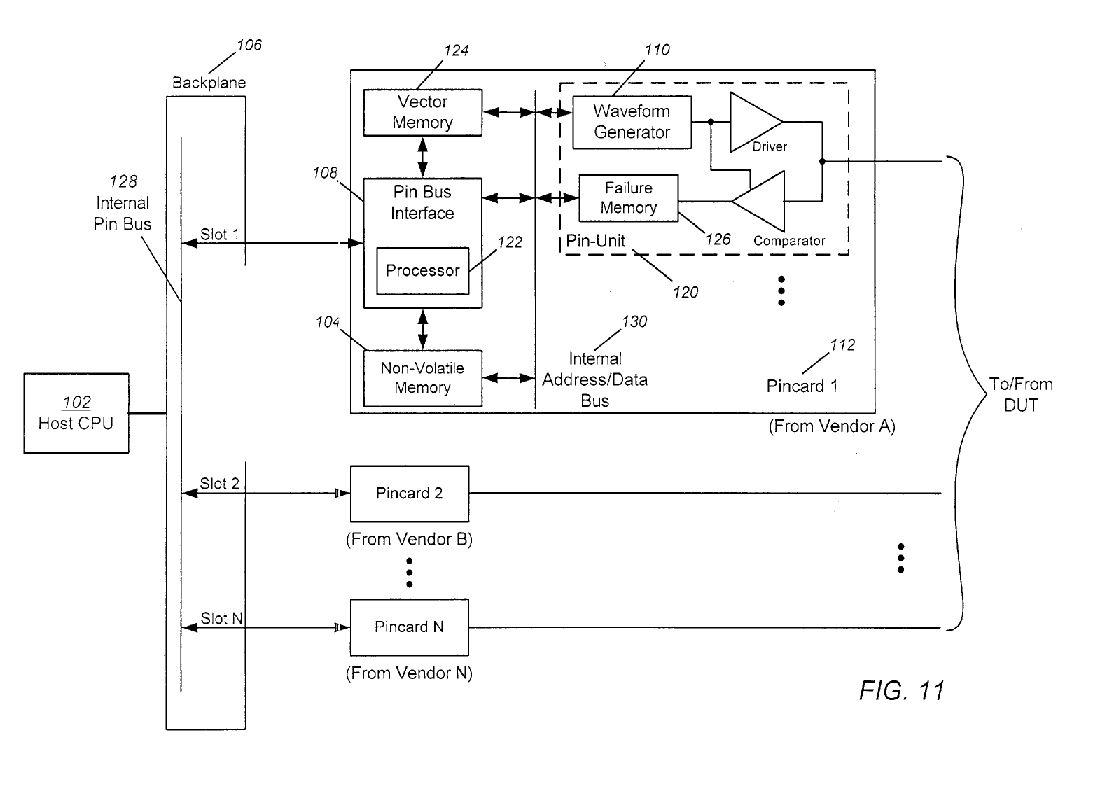

A more detailed block diagram of a pincard with non-volatile memory according to an open architecture embodiment of the present invention is shown in FIG. 11. For purposes of simplifying the figure and the description only, one pin-unit 120 per pincard 112 is illustrated. Each pin-unit 120 is associated with one tester channel. In general, each pincard 112 will have multiple pin-units 120 such as eight or 16 pin-units. As shown in FIG. 11, each pincard 112 has a local controller 122 such as an embedded microprocessor that can read the calibration data from non-volatile memory 104 and write to pin-unit registers.

An internal pin bus 128 in backplane 106 is accessible by either the embedded processor 122 or an external host central processing unit (CPU) 102. The host CPU 102 may be contained in a host computer such as a work station having a UNIX, Windows NT, or Linux operating system. The host computer functions as a user interface to enable a user to instruct the start and stop operation of the test, to load a test program and other test conditions or to perform test result analysis in the host computer. The host computer interfaces with the test system through the internal pin bus 128 and pin bus interface (PBI) circuitry 108 in each pincard 112. The PBI 108, which includes processor 122, provides a synchronous bus protocol between the tester controller (host CPU 102) and the pincard processor 122. Although not shown, the host computer is preferably connected to a communication network to send or receive test information from other test systems or computer networks.

An internal address/data bus 130 within each pincard 112 is connected to most of the functional blocks in the pincard such as the processor 122, vector memory 124, non-volatile memory 104, failure memory 126, and waveform generator 110. The processor 122 provides instructions to other functional blocks in the test system based on the test program and conditions from the host computer. The failure memory 126 stores test results, such as failure information of the DUT. The information stored in the failure memory 126 is used in the failure analysis stage of the DUT.

The flash or non-volatile memory 104 contains a status register containing several bits that will either control operations to be performed on the DUT or show a status of a command already in progress. This register can be polled during commands that require a relatively long time to complete. For example, a bulk erase (BE) command will require a three second time period to complete. The page program (PP) and sector erase (SE) commands also require time periods in excess of one second. During these operations, only status register read operations (RDSR) may be accepted, and all others are ignored. Each of these commands (PP, SE, and BE) are used frequently. The BE and SE commands are used under two circumstances: (1) during initial programming of data, and (2) during the updating of values stored in the memory. The flash or non-volatile memory 104 erase commands set each bit in the register to a logical high. The PP process can only set a bit to a logical low. Updating the data stored in the flash or non-volatile memory 104 requires the following sequence of operations: (1) reading all data from the sector containing the value to be changed, (2) issuing an SE command to erase the sector, and (3) issuing the PP commands to write all of the data back into the sector. Included in this data is the updated value(s).

Examples of calibration data that may be stored in the non-volatile memory 104 of pincard 112 as shown in FIG. 11 includes, but is not limited to: (i) compensation of reference driving voltages; (ii) compensation of reference comparison voltages; (iii) compensation of driving current loads; (iv) compensation of parametric measurement circuits connected to the test pins; (v) compensation of timing strobes used to trigger comparisons; and (vi) compensation of timing triggers used to drive test pin stimuli.

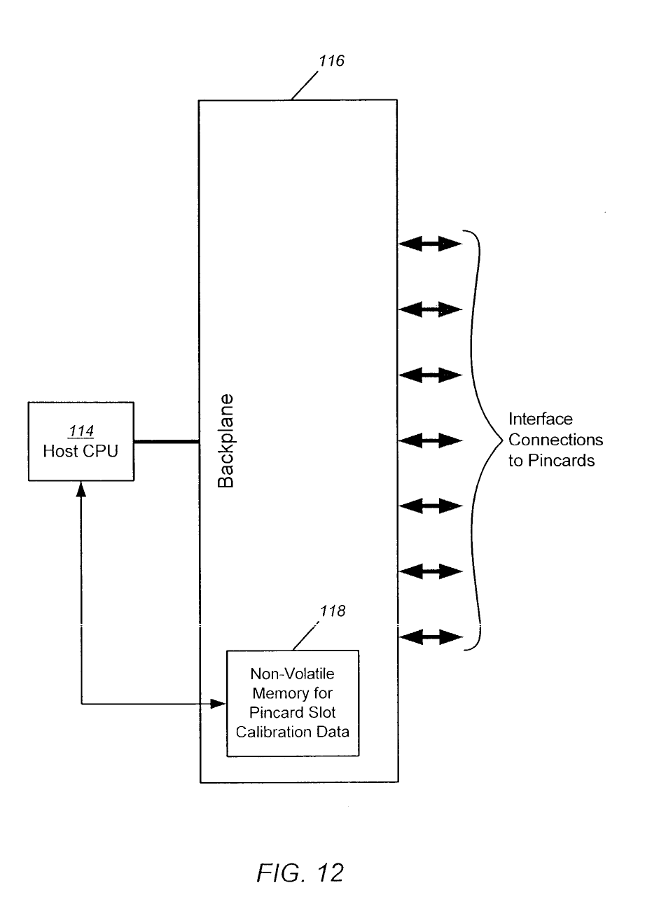

Because calibration data related to pincard slots (i.e. slot-to-slot skew) is test system dependent and not pincard dependent, pincard slot calibration data cannot be initially stored in pincard nonvolatile memory. However, it is possible to store pincard slot calibration data elsewhere, and once a pincard is installed into a particular slot, transfer the pincard calibration data specific to that particular slot into the pincard's non-volatile memory. In one embodiment of the present invention illustrated in FIG. 12, calibration data related to pincard slots may be initially stored in nonvolatile memory 118 on the backplane 116 and, under control of the host central processing unit (CPU) 114, either used directly from the memory 118 to calibrate the pincard, or transferred to the nonvolatile memory on the pincard prior to use. This transfer may take place automatically, upon power up of the system, or it may occur at the direction of a user command. In another embodiment, system ROM can be used to initially store pincard slot calibration data.

In an example implementation, the non-volatile memory on a pincard can hold two binary 32-bit calibration data entries for each pin-unit, a correction offset to the reference driving voltage and a correction offset to the reference comparison voltage. The non-volatile memory can be addressable and formatted as an array of a “C” language structure. In such an arrangement, the pin-unit registers are addressable and formatted as an array of a “C” language structure. For example, memory can be named “CALIBRATION_MEMORY” and an array for each pin-unit can be named “PIN_UNIT”. When a pincard is placed in a test system and power is applied, the embedded processor will run power up functions to initialize and start a calibration configuration routine.

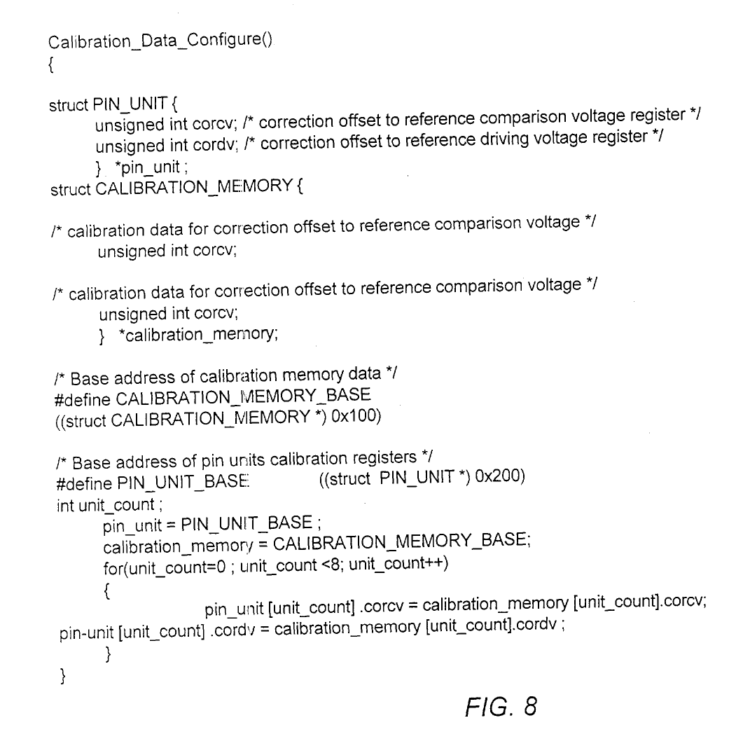

FIG. 8 shows an example of program written in “C” programming language for initiating a calibration process at the time of power up in the test system. In this “C” language example, the non-volatile memory is addressed by the name of “CALIBRATION_MEMORY” and the pin units are addressed by the name of “PIN_UNIT”. When the power is applied to the test system, the embedded processor in the pin card executes the power up functions to initialize itself and starts the calibration process. The description in FIG. 8 is merely an example and many other ways of conducting the calibration are possible within the concept of the present invention, such as an array structure implemented in an assembly language of the embedded processor.

For purposes of simplifying the disclosure, only the storage of calibration data has been described herein. However, the method and apparatus of the present invention can also be used to store other information locally on each pincard. For example, test conditions and test sequences can be stored in a similar manner locally on each pincard using non-volatile memory such as an EEPROM or flash memory. With regard to test sequences, because ICs are often tested using a variety of tests such as parametric tests, AC tests, DC tests, functional tests, scan tests, and the like, test sequences describe the order in which these tests are applied to the IC. With regard to test conditions, it should be understood that each test may contain multiple patterns. For example, the functional test of a two input gate has 4 patterns (00, 01, 10, 11). Patterns are binary tuples applied at the inputs of IC. Each test may also require the specification of certain conditions, such as voltage and current levels at the I/O pins (e.g., Vih, Vil, Voh, Vol, Iil, Iih, Iol and Ioh). Other test conditions may be timing related; such as the time duration of a strobe, a wait time, and the like. Test sequences, test conditions, and vectors for each test are described by a test program. As a tester executes this test program, the test sequences, test conditions, and vectors are applied to the IC.

According to the present invention, the semiconductor test system is configured to include a non-volatile memory storing calibration data in each pin card to compensate the error factors in all pin units in the pin card. Because the memory storing the calibration data is fixedly provided to the pin card, management of the calibration data by a manufacturer and a user is simplified such as in an inventory process, pin card replacement, updating the calibration data, and etc. Since pin card includes a local microprocessor, a calibration process including data mapping for the pin units in the pin card is also simplified. According to the present invention, the event based test system is able to achieve a cost effective, error free, secure and simple way of managing the calibration data for all of the pin cards.

Although only a preferred embodiment is specifically illustrated and described herein, it will be appreciated that many modifications and variations of the present invention are possible in light of the above teachings and within the purview of the appended claims without departing the spirit and intended scope of the invention.

What is claimed is:

1. A semiconductor test system for testing a semiconductor device under test (DUT) having a large number of test channels by applying test patterns to device pins of the DUT through the test channels and examining response outputs of the DUT, comprising:
a plurality of pin cards, each having a plurality of pin units therein to establish a part of the test channels;
a non-volatile memory provided within each pin card for storing calibration data for compensating error factors involved in the pin units mounted in a corresponding pin card; and
a microprocessor provided within each pin card for managing the calibration data and executing a calibration procedure for all of the pin units in the corresponding pin card.

2. A semiconductor test system as defined in claim 1, wherein the calibration data includes data for compensating error factors regarding parameters used in the corresponding pin card in testing the DUT.

3. A semiconductor test system as defined in claim 1, wherein the calibration data includes data for compensating error factors including timings and reference voltages of test patterns, timings of strobe signals and reference comparison voltages.

4. A semiconductor test system as defined in claim 1, further comprising:
a performance board unique to the DUT for mounting the DUT thereon and having signal paths for transmitting signals to and from the DUT; and
a pin fixture provided between the performance board and the main frame of the test system for interconnecting the plurality of pin cards in the test system with the performance board.

5. A semiconductor test system as defined in claim 4, wherein the calibration data includes data for compensating error factors including timings and reference voltages of test patterns, timings of strobe signals, reference comparison voltages, and signal propagation delays in the performance board and pin fixture.

6. A test system for testing devices, comprising:
a plurality of pincards, each pincard including a plurality of pin units for providing test signals to and analyzing output data from a device under test (DUT); and
a local non-volatile memory located on each pincard for storing calibration data and adapting the plurality of pin units on that pincard to compensate for expected signal degradations in accordance with the calibration data without a need to retrieve the calibration data from external storage.

7. The test system as recited in claim 6, further comprising a processor located on each pincard for managing the calibration data and executing a calibration procedure.

8. The test system as recited in claim 7, wherein the non-volatile memory is formatted as an array of addressable registers, each register associated with one or more pin units for storing calibration data for that pin unit.

9. The test system as recited in claim 8, wherein the non-volatile memory is formatted as an array of a high level programming language.

10. The test system as recited in claim 6, wherein the calibration data stored in the non-volatile memory of each pincard includes pincard calibration data which compensates for degradations caused by that pincard.

11. The test system as recited in claim 6, further comprising a loadboard and socket coupled to the plurality of pincards for retaining the DUT and making electrical connections between the plurality of pincards and the DUT.

12. The test system as recited in claim 11, wherein the calibration data stored in the non-volatile memory of one or more pincards includes loadboard and socket calibration data which compensates for degradations caused by the loadboard and socket.

13. The test system as recited in claim 11, further comprising nonvolatile memory on the loadboard for storing loadboard and socket calibration data accessible by the plurality of pincards for compensating for degradations caused by the loadboard and socket.

14. The test system as recited in claim 11, further comprising:
a host computer for controlling tests performed by the plurality of pincards;
a backplane for coupling the host computer to the plurality of pincards; and
a plurality of pincard slots for supporting the plurality of pincards and coupling the plurality of pincards to the backplane and the loadboard.

15. The test system as recited in claim 14, further including nonvolatile memory embedded in the backplane for storing calibration data related to skew between pincard slots.

16. The test system as recited in claim 6, wherein the non-volatile memory of one or more pincards includes test condition data.

17. The test system as recited in claim 6, wherein the non-volatile memory of one or more pincards includes test sequence data.

18. In a test system for testing devices, the test system capable of accepting a plurality of pincards, each pincard including a plurality of pin units for providing test signals to and analyzing output data from a device under test (DUT), a method for storing calibration data and compensating for signal degradations, comprising:
storing calibration data in a local nonvolatile memory on each pincard and adapting the plurality of pin units on that pincard to compensate for expected signal degradations in accordance with the calibration data without a need to retrieve the calibration data from external storage.

19. The method for storing calibration data as recited in claim 18, wherein for each pincard, the method further comprises managing the calibration data and executing a calibration procedure.

20. The method for storing calibration data as recited in claim 19, further comprising formatting the non-volatile memory of each pincard as an array of addressable registers, each register associated with one or more pin units in that pincard for storing calibration data for that pin unit.

21. The method for storing calibration data as recited in claim 20, further comprising formatting the non-volatile memory as an array of a high level programming language.

22. The method for storing calibration data as recited in claim 18, further comprising storing pincard calibration data in the non-volatile memory of each pincard for compensating for degradations caused by that pincard.

23. The method for storing calibration data as recited in claim 18, further comprising retaining the DUT in a loadboard and socket and making electrical connections between the plurality of pincards and the DUT via the loadboard and socket.

24. The method for storing calibration data as recited in claim 23, further comprising storing loadboard and socket calibration data in the non-volatile memory of one or more pincards for compensating for degradations caused by the loadboard and socket.

25. The method for storing calibration data as recited in claim 23, further comprising storing loadboard and socket calibration data in a nonvolatile memory on the loadboard accessible by the plurality of pincards for compensating for degradations caused by the loadboard and socket.

26. The method for storing calibration data as recited in claim 23, the test system further comprising a host computer for controlling tests performed by the plurality of pincards and a backplane for coupling the host computer to the plurality of pincards, the method further comprising:
supporting the plurality of pincards in a plurality of pincard slots and coupling the plurality of pincards to the backplane and the loadboard via the plurality of pincard slots.

27. The method for storing calibration data as recited in claim 26, further comprising storing and retrieving calibration data related to skew between pincard slots from nonvolatile memory embedded in the backplane.

28. The method for storing calibration data as recited in claim 18, further comprising storing test condition data in the non-volatile memory of one or more pincards.

29. The method for storing calibration data as recited in claim 18, further comprising storing test sequence data in the non-volatile memory of one or more pincards.
